(19) United States
(12) Patent Application Publication
(10) Pub. No.: US 2012/0291855 A1
(43) Pub. Date: Nov. 22, 2012

(54) SOLAR TILE STRUCTURE

(76) Inventors: Shih-Wei Lee, Kaohsiung City (TW); Chih-Wei Tseng, Kaohsiung City (TW); Chio-An Tseng, Kaohsiung City (TW); Yen-Chun Chen, Taoyuan County (TW); Fu-Lu Jian, Kaohsiung City (TW)

(21) Appl. No.: 13/205,633

(22) Filed: Aug. 9, 2011

(30) Foreign Application Priority Data
May 20, 2011 (TW) 100209098

(51) Int. Cl. H01L 31/048

(52) U.S. Cl. 136/251

(57) ABSTRACT

A solar tile structure includes a base, a first hook structure disposed on a first side of the base, a second hook structure dispose on a second side of the base opposite to the first side for engaging with a hook structure of an adjacent solar tile structure so as to constrain the relative movement of the base and the adjacent solar tile structure, a first slot structure disposed on a third side of the base different from the first side for draining water from the base, and a second slot structure disposed on a fourth side of the base opposite to the third side for engaging with a slot structure of other adjacent solar tile structure so as to constrain the relative movement of the base and the other adjacent solar tile structure. A combination of solar tile structures is also provided.

### BACKGROUND OF THE INVENTION

1. Field of the Invention

The invention relates to a solar tile structure, and more particularly, to a solar tile structure adapted to engage with an adjacent tile structure and capable of draining liquid.

2. Description of the Prior Art

Generally, a conventional solar panel can be disposed on an outside surface of a building. For example, the conventional solar panel can be installed on a housetop or an external wall so as to transform solar energy into electrical energy effectively. The conventional solar panel disposed on the housetop of the building can transform the solar energy into the electrical power in a sunny day and can protect the building in a rainy day. However, the conventional solar panel tile can not drain water away from the solar panel effectively in the rainy day, so that electronic elements inside the solar panels of the conventional solar panel tile are damaged by the water easily. Thus, design of a solar panel tile structure capable of draining the water around the solar panel effectively is an important issue in the solar panel industry.

Please refer to FIG. 1. FIG. 1 is a diagram of a tile structure combination 90 in the prior art. The tile structure combination 90 includes a first tile unit 92 and a second tile unit 94. The first tile unit 92 includes an upper hook 921 and a lower hook 923, and the second tile unit 94 includes an upper hook 941 and a lower hook 943. The two tile units engage with each other by the upper hooks and the lower hooks to engage with each other, so as to form the tile structure combination 90. For example, the lower hook 923 of the first tile unit 92 is engaged with the upper hook 941 of the second tile unit 94. The first tile unit 92 and the second tile unit 94 can utilize the individual upper and lower hooks to engage with the adjacent tile unit for forming the tile structure combination 90. However, the conventional tile structure can not drain water effectively.

### SUMMARY OF THE INVENTION

The invention provides a solar tile structure adapted to engage with an adjacent tile structure and capable of draining liquid for solving above drawbacks.

According to the claimed invention, a solar tile structure includes a base whereon an accommodating space is formed, and the accommodating space is for accommodating a solar panel. The solar tile structure further includes a first hook structure disposed on a first side of the base, a second hook structure disposed on a second side of the base opposite to the first side for engaging with an adjacent solar tile structure so as to constrain a movement of the base relative to the adjacent solar tile structure, a first slot structure disposed on a third side of the base different from the first side for draining liquid from the base, and a second slot structure disposed on a fourth side of the base opposite to the third side for engaging with other adjacent solar tile structure so as to constrain a movement of the base relative to the other adjacent solar tile structure.

According to the claimed invention, a guiding structure is formed on an end of the first hook structure.

According to the claimed invention, the solar tile structure further includes a buckling structure disposed on the first side of the base for buckling a roof.

According to the claimed invention, a plurality of holes are formed on a surface of the base adjacent to the first side, the solar tile structure further comprises a plurality of locking components, and each locking component is adapted to pass through the corresponding hole for fixing the base on a roof.

According to the claimed invention, the first slot structure includes a first channel for draining the liquid, and a second channel disposed by a side of the first channel for draining the liquid overflowing from the first channel.

According to the claimed invention, the solar tile structure further includes a connecting module disposed on a surface of the base different from the solar panel.

According to the claimed invention, a front end of the first hook structure and a front end of the second hook structure respectively are toward different directions, and a front end of the first slot structure and a front end of the second slot structure respectively are toward different directions.

According to the claimed invention, a solar tile structure combination includes a first solar tile structure, and a second solar tile structure combined with the first solar tile structure. The first solar tile structure includes a first base whereon a first accommodating space is formed, and the first accommodating space is for accommodating a first solar panel. The first solar tile structure further includes a first hook structure disposed on a first side of the first base, a second hook structure dispose on a second side of the first base opposite to the first side, a first slot structure disposed on a third side of the first base different from the first side, and a second slot structure disposed on a fourth side of the first base opposite to the third side. The second solar tile structure includes a second base whereon a second accommodating space is formed, and the second accommodating space is for accommodating a second solar panel. The second solar tile structure further includes a third hook structure disposed on a first side of the second base, a fourth hook structure dispose on a second side of the second base opposite to the first side for engaging with the first hook structure of the first solar tile structure so as to constrain a movement of the second base relative to the first solar tile structure, a third slot structure disposed on a third side of the second base different from the first side, and a fourth slot structure disposed on a fourth side of the second base opposite to the third side.

The solar tile structure of the invention can drain the water on the base effectively, and each solar tile structure can be combined with the adjacent solar tile structures rapidly and stably for forming the solar tile structure combination. Thus, the solar tile structure combination of the invention with enhanced draining system has advantages of simple structure and easy assembly. The invention can decrease catchment on the solar panel for preventing the solar panel from short.

These and other objectives of the invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a tile structure combination in the prior art.

FIG. 2 is a diagram of a solar tile structure combination according to an embodiment of the invention.

FIG. 3. is a diagram of a solar tile structure according to the embodiment of the invention.

FIG. 4 to FIG. 6 respectively are diagrams of the solar tile structure in different views according to the embodiment of the invention.

FIG. 7 and FIG. 8 respectively are enlarged diagrams of the solar tile structure combination in different views according to the embodiment of the invention.

### DETAILED DESCRIPTION

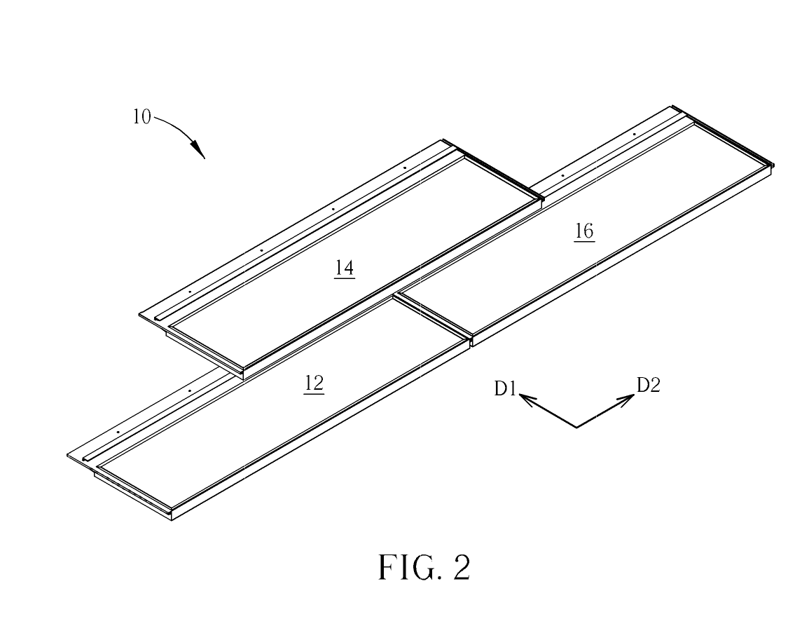

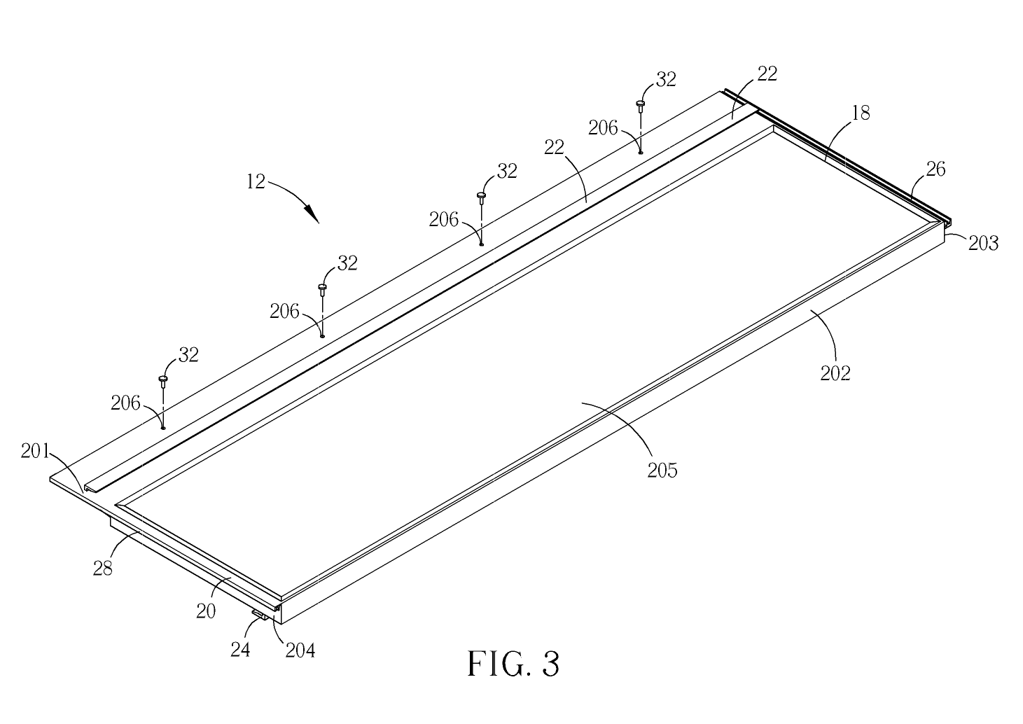

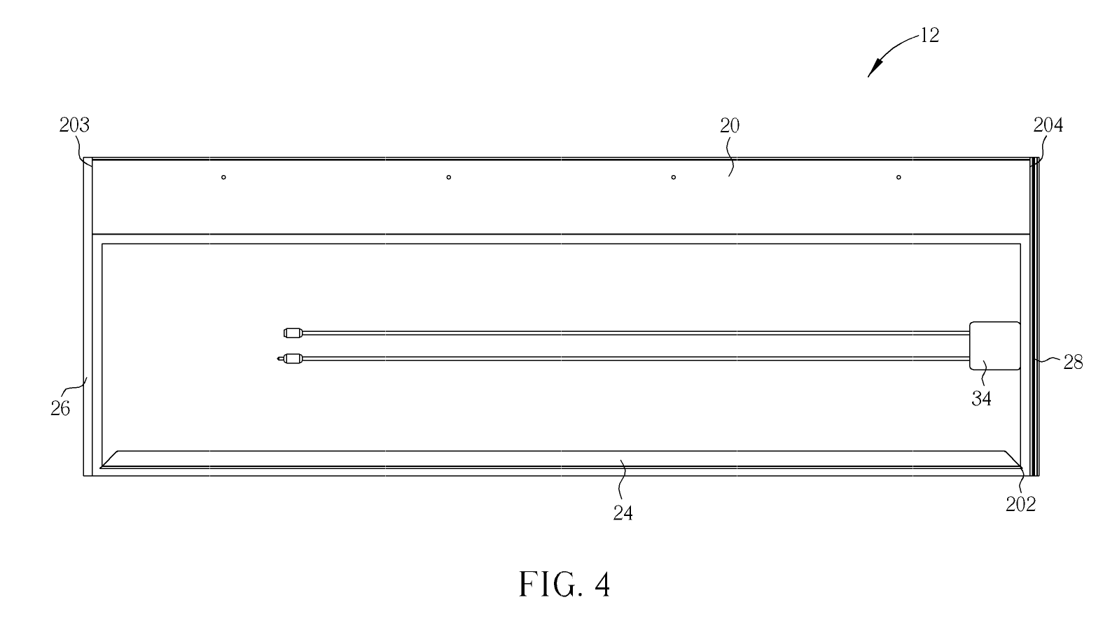

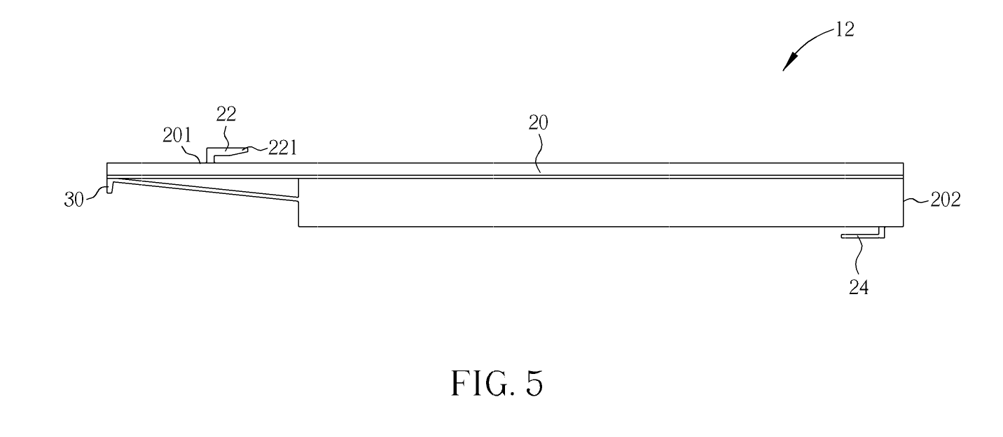

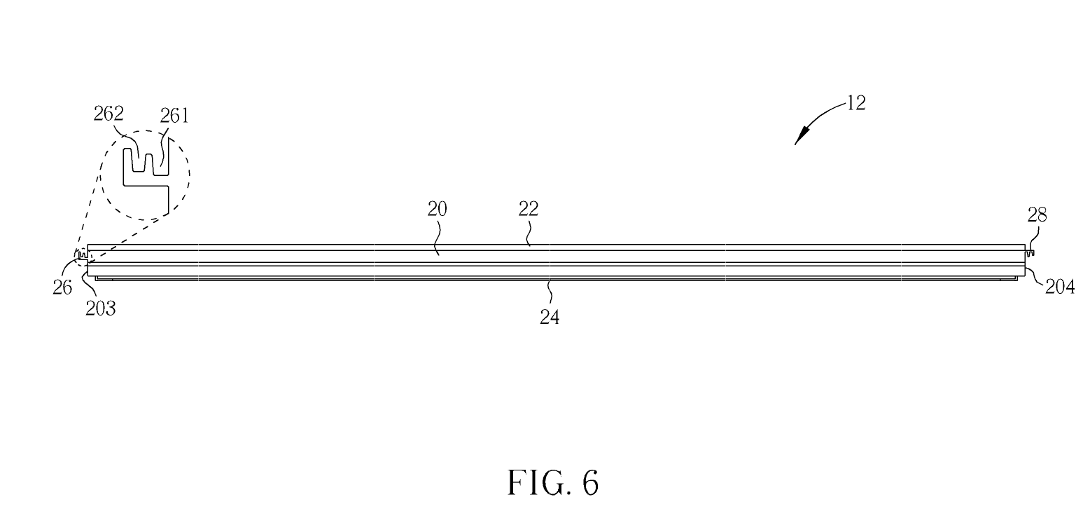

Please refer to FIG. 2. FIG. 2 is a diagram of a solar tile structure combination 10 according to an embodiment of the invention. The solar tile structure combination 10 can be composed of a first solar tile structure 12, a second solar tile structure 14 and a third solar tile structure 16 side by side. An amount of the solar tile structure is not limited to the above-mentioned embodiment, and it depends on actual demand. Please refer to FIG. 3 to FIG. 6. FIG. 3. is a diagram of the first solar tile structure 12 according to the embodiment of the invention. FIG. 4 to FIG. 6 respectively are diagrams of the first solar tile structure 12 in different views according to the embodiment of the invention. The first solar tile structure 12 can be for accommodating a first solar panel 18, and the first solar panel 18 transforms solar energy into electric power, so that the first solar tile structure 12 has functions of sheltering and powering when being installed on a roof.

As shown in FIG. 3 to FIG. 6, the first solar tile structure 12 includes a first base 20 whereon a first accommodating space 205 is formed. The first accommodating space 205 is for accommodating the first solar panel 18. The first solar tile structure 12 further includes a first hook structure 22 disposed on a first side 201 of the base 20, a second hook structure 24 disposed on a second side 202 of the first base 20 opposite to the first side 201, a first slot structure 26 disposed on a third side 203 of the first base 20 different from the first side 201, and a second slot structure 28 disposed on a fourth side 204 of the first base 20 opposite to the third side 203. The first slot structure 26 can include a first channel 261 and a second channel 262. The first channel 261 is for draining liquid from the first base 20. The second channel 262 is normally disposed by a side of the first channel 261 for draining the liquid overflowing from the first channel 261, so as to drain the liquid from the first base 20 with the first channel 261.

The first hook structure 22 and the second hook structure 24 can respectively be disposed on the first side 201 and the second side 202 of the first base 20 (the upper side and the lower side), and a front end of the first hook structure 22 and a front end of the second hook structure 24 respectively are toward different directions. For example, the front end of the first hook structure 22 and the front end of the second hook structure 24 are toward inner area of the first solar tile structure 12 oppositely. The first solar tile structure 12 can be combined with the adjacent solar tile structures via the first hook structure 22 and the second hook structure 24 for forming the solar tile structure combination 10. The first slot structure 26 and the second slot structure 28 are respectively disposed on the third side 203 and the fourth side 204 of the first base (the lift side and the right side), and front ends of the two slot structures respectively are toward different directions. For example, the first end of the first slot structure 26 is toward an upper side of the first solar tile structure 12, and the front end of the second slot structure 28 is toward a lower side of the first solar tile structure 12. The first solar tile structure 12 can be combined with the adjacent solar tile structures via the first slot structure 26 and the second slot structure 28 for forming the solar tile structure combination 10, an assembly of the slot structures drains the liquid from the solar tile structure combination 10, and a detailed description is introduced as follows.

In addition, a guiding structure 221 can be formed on an end of the first hook structure 22 of the first solar tile structure 12. The first hook structure 22 of the first solar tile structure 12 can be smoothly engaged with the hook structure of the adjacent solar tile structure via the guiding structure 221. The first solar tile structure 12 can further include a first buckling structure 30 disposed on the first side 201 of the first base 20 for buckling the roof. A plurality of holes 206 can be formed on a surface of the first base 20 adjacent to the first side 201 of the first solar tile structure 12. The first solar tile structure 12 can further include a plurality of locking components 32. Each locking component 32 can pass through the corresponding hole 206, so as to fix the first base 20 on the roof. The first solar tile structure 12 can further include a first connecting module 34 disposed on a surface of the first base 20 different from the first solar panel 18 for outputting the electric power generated by the first solar panel 18.

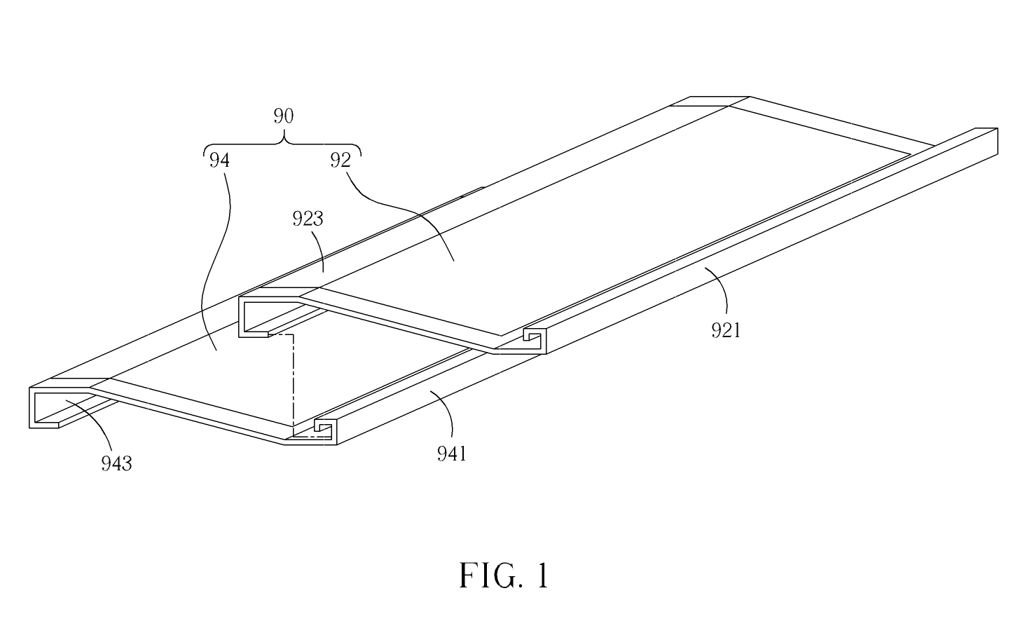

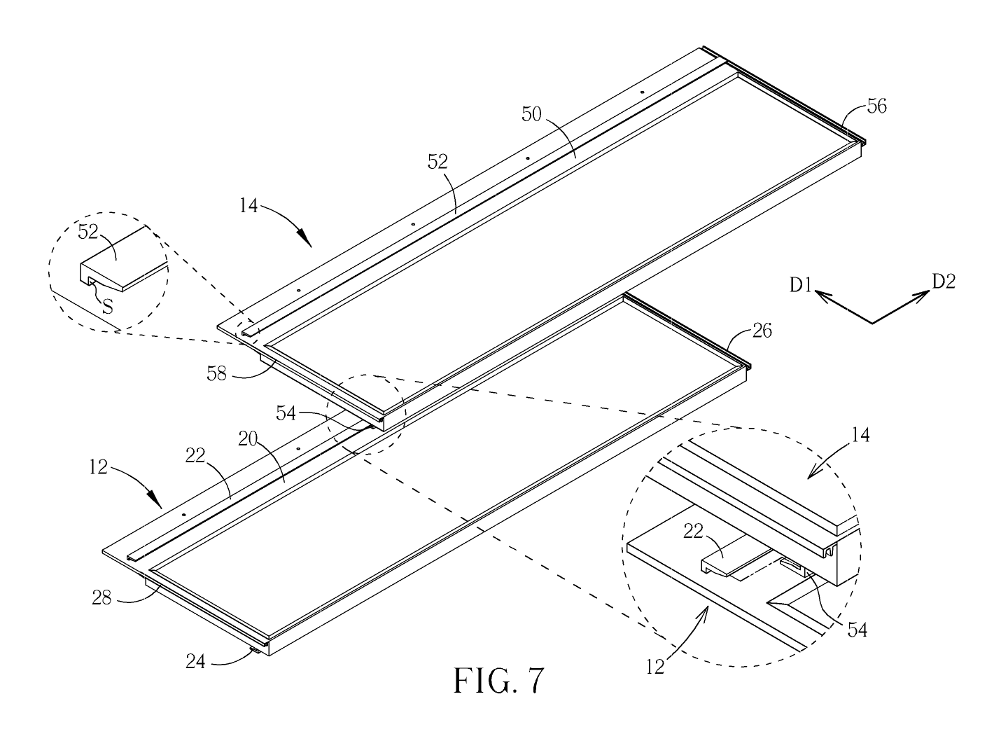

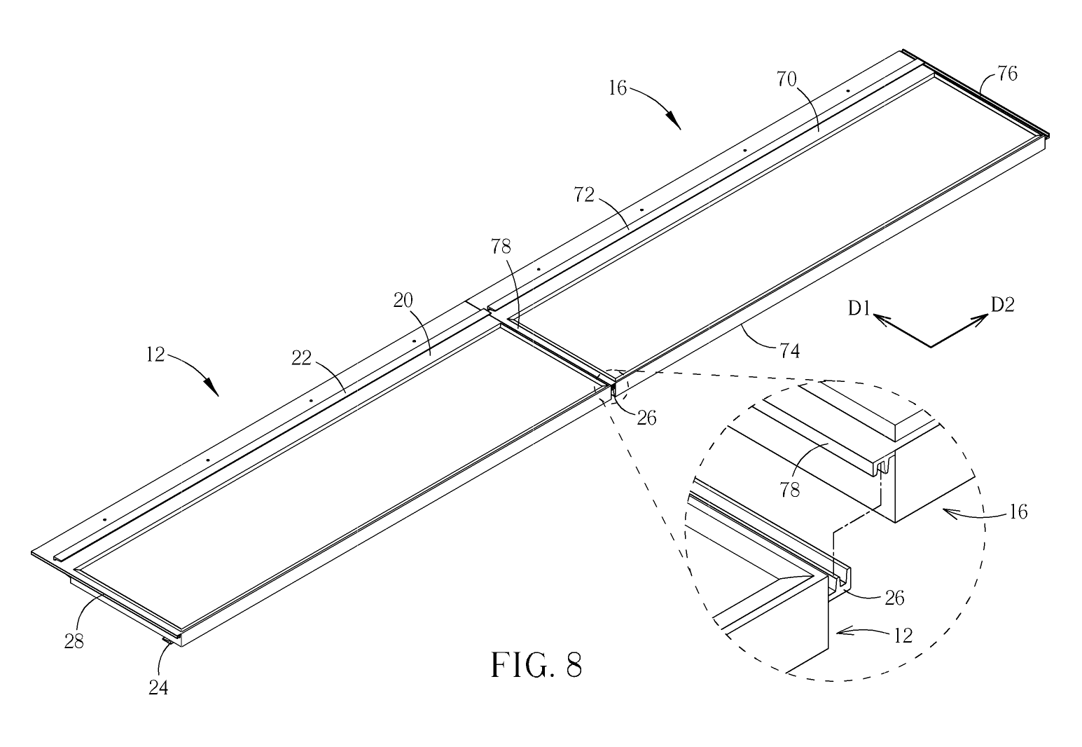

Please refer to FIG. 1, FIG. 7 and FIG. 8. FIG. 7 and FIG. 8 respectively are enlarged diagrams of the solar tile structure combination 10 in different views according to the embodiment of the invention. The second solar tile structure 14 includes a second base 50, a third hook structure 52, a fourth hook structure 54, a third slot structure 56 and a fourth slot structure 58. A second accommodating space is formed on the second base 50 for accommodating a second solar panel. The third solar tile structure 16 includes a third base 70, a fifth hook structure 72, a sixth hook structure 74, a fifth slot structure 76 and a sixth slot structure 78. A third accommodating space is formed on the third base 70 for accommodating a third solar panel. Structures and functions of the second solar tile structure 14 and the third solar tile structure 16 are the same as the first solar tile structure 12, and detailed description is omitted herein for simplicity. As shown in FIG. 7, the fourth hook structure 54 of the second solar tile structure 14, which is toward the first direction D1, can be engaged with the first hook structure 22 of the first solar tile structure 12, which is toward a direction opposite to the first direction D1, and the second base 50 does not move relative to the first base 20 at the first direction D1, so that the second solar tile structure 14 can be combined with the first solar tile structure 12 in the first direction D1. In addition, as shown in FIG. 8, the sixth slot structure 78 of the third solar tile structure 16, which is toward the bottom of the solar tile structure combination 10, can be engaged with the first slot structure 26 of the first solar tile structure 12, which is toward the top of the solar tile structure combination 10, so that the third base 70 does not move relative to the first base 20 at a second direction D2 perpendicular to the first direction D1, and the third solar tile structure 16 can be combined with the first solar tile structure 12 in the second direction D2. As the above-mentioned, the solar tile structures can be combined with one another in the first direction D1 and the second direction D2, as shown in FIG. 1, FIG. 7 and FIG. 8, for forming the solar tile structure combination 10 stably.

Besides, the liquid (such as rainwater) can flow toward the first solar tile structure 12 or the third solar tile structure 16 at the direction opposite to the first direction D1 when the rainwater falls on the second base 50 of the second solar tile structure 14. The rainwater can further flow toward two lateral sides of the second base 50, and then flow onto the first base 20 and the third base 70 via the third slot structure 56 and the fourth slot structure 58. After, the rainwater on the first base 20 (or the third base 70) can flow at the direction opposite to the first direction D1, or can flow into the first slot structure 26 and the second slot structure 28 (or the fifth slot structure 76 and the sixth slot structure 78) via the corresponding first channel 261 and the second channel 262 for draining the rainwater. The sixth slot structure 78 not only can constrain a movement of the third base 70 relative to the first base 20, but also can drain the liquid via the first slot structure 26. Furthermore, the liquid on the second base 50 can flow at the first direction D1 as being driven by wind at the first direction D1. As shown in FIG. 7, the liquid is blocked by a wall S of the third hook structure 52 and flows into the third slot structure 56 and the fourth slot structure 58 via the lateral sides of the second base 50, and then falls onto the third base 70 and the first base 20. Therefore, the liquid can flow into the slot structures via the lateral sides of the base when falling on the first base 20 or the third base 70, so that no matter how the wind blows, the solar tile structure combination 10 has preferred draining function for preventing the flooded solar panel from short.

Comparing to the prior art, the solar tile structure of the invention can drain the water on the base effectively, and each solar tile structure can be combined with the adjacent solar tile structures rapidly and stably for forming the solar tile structure combination. Thus, the solar tile structure combination of the invention with enhanced draining system has advantages of simple structure and easy assembly. The invention can decrease catchment on the solar panel for preventing the solar panel from short.

Those skilled in the art will readily observe that numerous modifications and alterations of the device and method may be made while retaining the teachings of the invention.

What is claimed is:

1. A solar tile structure, comprising:
a base whereon an accommodating space is formed, the accommodating space being for accommodating a solar panel;
a first hook structure disposed on a first side of the base;
a second hook structure disposed on a second side of the base opposite to the first side for engaging with an adjacent solar tile structure so as to constrain a movement of the base relative to the adjacent solar tile structure;
a first slot structure disposed on a third side of the base different from the first side for draining liquid from the base; and
a second slot structure disposed on a fourth side of the base opposite to the third side for engaging with other adjacent solar tile structure so as to constrain a movement of the base relative to the other adjacent solar tile structure.

2. The solar tile structure of claim 1, wherein a guiding structure is formed on an end of the first hook structure.

3. The solar tile structure of claim 1, further comprising:
a buckling structure disposed on the first side of the base for buckling a roof.

4. The solar tile structure of claim 1, wherein a plurality of holes are formed on a surface of the base adjacent to the first side, the solar tile structure further comprises a plurality of locking components, and each locking component is adapted to pass through the corresponding hole for fixing the base on a roof.

5. The solar tile structure of claim 1, wherein the first slot structure comprises a first channel for draining the liquid, and a second channel disposed by a side of the first channel for draining the liquid overflowing from the first channel.

6. The solar tile structure of claim 1, further comprising:
a connecting module disposed on a surface of the base different from the solar panel.

7. The solar tile structure of claim 1, wherein a front end of the first hook structure and a front end of the second hook structure respectively are toward different directions.

8. The solar tile structure of claim 1, wherein a front end of the first slot structure and a front end of the second slot structure respectively are toward different directions.

9. A solar tile structure combination, comprising:
a first solar tile structure, comprising:
a first base whereon a first accommodating space is formed, the first accommodating space being for accommodating a first solar panel;
a first hook structure disposed on a first side of the first base;
a second hook structure disposed on a second side of the first base opposite to the first side;
a first slot structure disposed on a third side of the first base different from the first side; and
a second slot structure disposed on a fourth side of the first base opposite to the third side; and
a second solar tile structure combined with the first solar tile structure, the second solar tile structure comprising:
a second base whereon a second accommodating space is formed, the second accommodating space being for accommodating a second solar panel;
a third hook structure disposed on a first side of the second base;
a fourth hook structure disposed on a second side of the second base opposite to the first side for engaging with the first hook structure of the first solar tile structure so as to constrain a movement of the second base relative to the first solar tile structure;
a third slot structure disposed on a third side of the second base different from the first side; and
a fourth slot structure disposed on a fourth side of the second base opposite to the third side.

10. The solar tile structure combination of claim 9, further comprising:
a third solar tile structure combined with the first solar tile structure, the third solar tile structure comprising:
a third base whereon a third accommodating space is formed, the third accommodating space being for accommodating a third solar panel;
a fifth hook structure disposed on a first side of the third base;
a sixth hook structure disposed on a second side of the third base opposite to the first side;
a fifth slot structure disposed on a third side of the third base different from the first side; and
a sixth slot structure disposed on a fourth side of the third base opposite to the third side for engaging with the first slot structure of the first solar tile structure.

11. The solar tile structure combination of claim 10, wherein the fourth hook structure is engaged with the fifth hook structure.

12. The solar tile structure combination of claim 9, wherein a guiding structure is formed on an end of the first hook structure.

13. The solar tile structure combination of claim 9, wherein the first solar tile structure further comprises:
a first buckling structure disposed on the first side of the first base for buckling a roof.

14. The solar tile structure combination of claim 9, wherein a plurality of first holes are formed on a surface of the first base adjacent to the first side, the first solar tile structure further comprises a plurality of locking components, and each locking component is adapted to pass through the corresponding hole for fixing the first base on a roof.

15. The solar tile structure combination of claim 9, wherein the first slot structure comprises a first channel for draining the liquid, and a second channel disposed by a side of the first channel for draining the liquid overflowing from the first channel.

16. The solar tile structure combination of claim 9, wherein the first solar tile structure further comprises:
a connecting module disposed on a surface of the first base different from the first solar panel.

17. The solar tile structure combination of claim 9, wherein a front end of the first hook structure and a front end of the second hook structure respectively are toward different directions.

18. The solar tile structure combination of claim 9, wherein a front end of the first slot structure and a front end of the second slot structure respectively are toward different directions.
